(19) United States
(12) Patent Application Publication
(10) Pub. No.: US 2003/0161422 A1
(43) Pub. Date: Aug. 28, 2003

(54) Receiver and method for mitigating inter-code and inter-symbol interferences in a received signal

(76) Inventor: Hao Bi, Wheeling, IL (US)

Correspondence Address: MOTOROLA, INC., 1303 EAST ALGONQUIN ROAD, IL01/3RD, SCHAUMBURG, IL, 60196

(21) Appl. No.: 10/368,126

(22) Filed: Feb. 18, 2003

Related U.S. Application Data
(60) Provisional application No. 60/360,382, filed on Feb. 28, 2002.

(51) Int. Cl. H04L 1/00; H03D 1/06; H04B 1/10

(52) U.S. Cl. 375/348; 375/350

(57) ABSTRACT

Receiver and method for mitigating inter-code and inter-symbol interferences in a received signal. The inter-symbol interference caused by previous symbols, is replicated from previous received symbols and removed from the received baseband signal using a feedback loop, thereby producing a modified received baseband signal. A block filter is applied to the modified received baseband signal to decorrelate the received signals and to recover the transmitted symbols.

### REFERENCE(S) TO RELATED APPLICATION(S)

The present application claims priority from provisional application, Serial No. 60/360,382, entitled “Receiver and Method for Mitigating Inter-code and Inter-symbol Interferences in a Received Signal,” filed Feb. 28, 2002, which is commonly owned and incorporated herein by reference in its entirety.

### FIELD OF THE INVENTION

The present invention relates generally to the field of communication systems, and more particularly, to a receiver and method for mitigating inter-code and inter-symbol interferences in a received signal.

### BACKGROUND OF THE INVENTION

In 1xEV-DV and HSDPA (“Updated Joint Physical Layer Proposal for 1xEV-DV,” LG Electronics, et al. and “High Speed Downlink Packet Access: Physical Layer Aspects,” 3GPP TR 25.858, respectively) high speed data service is supported using high level modulations, such as 8-PSK and 16-QAM. High speed data service is also supported using multiple channelization codes with smaller spreading factors. Reception of 8-PSK and 16-QAM modulation symbols using a conventional RAKE receiver is very vulnerable in a multipath (dispersive) environment due to inter-code and inter-symbol interferences caused by diminished orthogonality among channelization codes. Such structured interferences severely limit system peak rate and throughput. According to a paper entitled “Service Requirements for HSDPA,” 12A010018, published by Vodaphone in April, 2001, high speed data service is considered to have most application in urban areas, where multipath channel is common.

Minimum Mean Square Error (MMSE) receivers together with decision-feedback equalizers have been studied. See M. Honig and M. Tsatsanis, “Adaptive Techniques for Multiuser CDMA Receivers,” IEEE Commun. Mag., pp. 49-61, May, 2000. Optimal MMSE receivers typically require training to search for filter coefficients. Training is not desired in a 1xEV-DV/HSDPA system because long codes (instead of short codes) are used and because transmission is not continuous when packet data services are the target applications. An MMSE equalizer is studied by C. D. Frank and E. Visotsky in “Adaptive Interference Suppression for Direct-Sequence CDMA Systems with Long Spreading Codes,” Proc. 36^{th} Annual Allerton Conference on Communication, Control and Computing, Monticello, Ill., September, 1998. This MMSE equalizer uses pilot channel for training, which means that desired coefficients can be searched for even when data is not transmitted. However, the technique disclosed resorts to long-term ergodicity instead of localized cross-correlations between codes, and therefore would not cancel the instantaneous inter-code interference. Inter-symbol interference cancellation is also not considered in the study.

A conventional RAKE receiver followed by a decision feedback equalizer has been proposed by NTT DoCoMo in “Multipath Interference Cancellation (MPIC) for HSDPA and Effect of 64QAM Data Modulation,” TSGR1#18(01)0102, January, 2001. The performance of this configuration is limited because a RAKE receiver cannot reduce inter-code interferences, and because the propagation of errors caused by inter-code interference further hampers the reduction of inter-symbol interference by the decision-feedback loop.

Thus, there is a need for a receiver for and method of mitigating inter-code and inter-symbol interferences in a communication signal.

### BRIEF DESCRIPTION OF THE DRAWINGS

FIG. 1 is a block diagram generally depicting a receiver for mitigating inter-code and inter-symbol interferences in a communication signal in accordance with the preferred embodiment of the invention.

FIG. 2 is a block diagram representation of the method of mitigating inter-code and inter-symbol interferences in a communication signal in accordance with the preferred embodiment of the present invention.

FIG. 3 is a flow chart of the method depicted in FIG. 2.

### DETAILED DESCRIPTION OF THE DRAWINGS

The present invention provides a receiver for and method of mitigating inter-code and inter-symbol interferences in a communication signal. Inter-code interferences are cancelled by rotating the receiving filter of a code channel toward the direction orthogonal to other received code channels. When combined with a feedback loop, the receiver and method of the present invention show resilient performance in a dispersive environment.

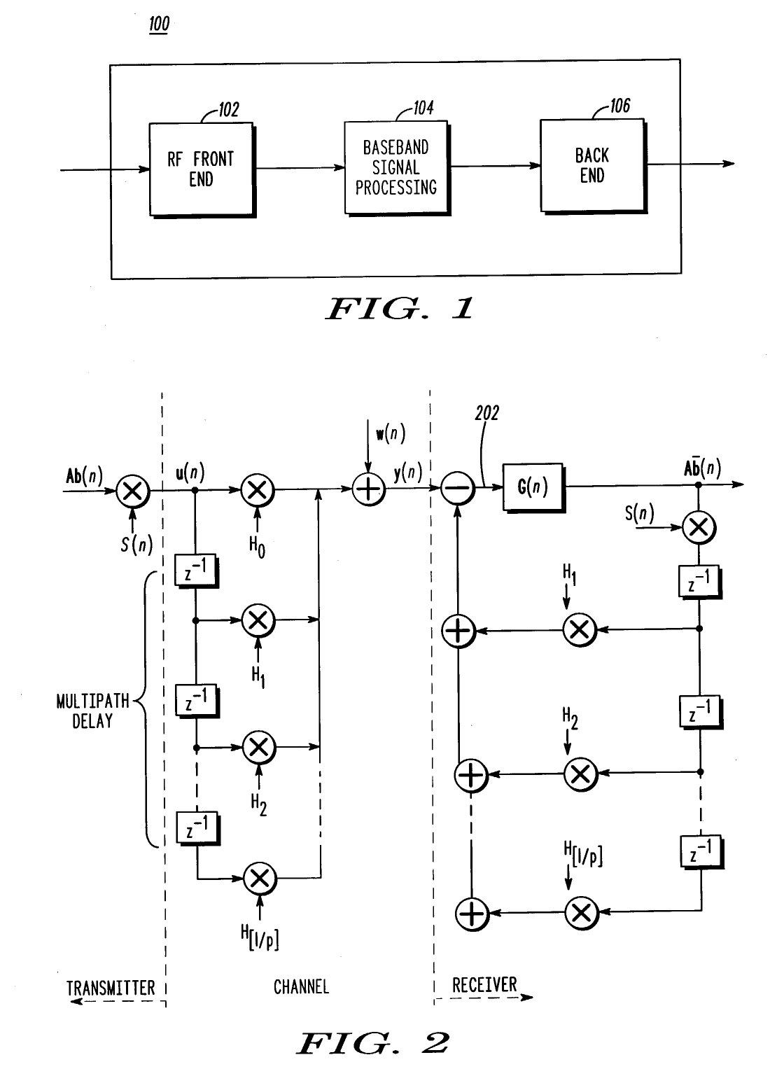

FIG. 1 is a block diagram of a pertinent part of a receiver 100 in accordance with the preferred embodiment of the present invention. The receiver 100 may be a receiver of a mobile station, a PC card, receivers of fixed wireless system, or the like. The receiver 100 includes an RF front end 102, a baseband signal processing block 104 and a baseband back end 106. The RF front end 102 receives signals from a transmitting device and converts the signals from radio frequency (RF) passband signals into baseband signals. The baseband signal processing block 104 receives the baseband signals and processes them to remove inter-code and inter-symbol interferences in accordance with the present invention. The recovered data is sent to the baseband back end 106 and output to the intended application (e.g., web browser, video service, File Transfer Protocol (FTP) service, etc.).

Let bₖ(n) denote the modulation symbol of code channel k at time n. The vector b(n)_{K×1}=[b₁(n) b₂(n) . . . b_{K}(n)]^{T} represents the modulation symbols of K code channels at time n. Let sₖ(n) denote a channelization code (combining a Walsh code with a transmitter specific scrambling code) for code channel k at symbol time n. sₖ(n) is a function of symbol time n when a long code (i.e., the code period is longer than a symbol duration) is used for scrambling, like in 1xEV-DV and HSDPA. sₖ(n) would be the same at all times n when a short code (i.e., the code period is equal to a symbol duration) is used for scrambling. The spreading length of sₖ(n) is P in chips.

Channelization codes of the K channels can be grouped into a matrix S(n)=[s₁(n) s₂(n) . . . s_{K}(n)]_{P×K}. A diagonal matrix A is used to represent the amplitudes of the code channels,

$$A = [ \begin{matrix}{a}_{1} & & & & \\ & ⋰ & & & \\ & & {a}_{k} & & \\ & & & ⋰ & \\ & & & & {a}_{K}\end{matrix} ]$$

where aₖ, 1≦k≦K, denotes the amplitude of code channel k. Amplitudes of code channels do not change during a packet transmission, thus the matrix A and aₖ, 1≦k≦K, are not indexed by n. Thus, a transmitted baseband signal can be represented as the product of the channelization codes of K channels, the amplitudes of the code channels and the modulation symbols of the code channels, or u(n)=S(n)·A·b(n). Let a vector h=[h(0) h(1) . . . h(L)]_{1×(L+1)} represent the effective baseband channel impulse response (convolution of transmitter filter, multipath channel impulse response, and receiver filter) between the baseband transmitter (not shown in FIG. 1) and the baseband signal processing block 104, where complex variable h(i), 0≦i≦L, denotes the amplitude and phase response of a path at delay i, and L is the maximum delay in chip units. Without loss of generality, delay of the first received path is set to 0 and delays of other paths are set according to their differences from the first received path. For simplicity of explanation, only delays in integer chips are considered herein; however, the generalization to sub-chip delays is straightforward and should be recognized by one of ordinary skill in the art. Channel matrices can then be constructed from h as

$${H}_{l} = {[ \begin{matrix}h ( lP ) & ⋯ & h ( lP - P + 1 ) \\ ⋮ & ⋰ & ⋮ \\ h ( lP + P - 1 ) & ⋯ & h ( lP )\end{matrix} ]}_{P \times P} , 0 \leq l \leq ⌈ \frac{L}{P} ⌉ \qquad ( 1 )$$

where [x] denotes the smallest integer number equal to or larger than x. With these denotations and referring to FIG. 2, the baseband signals at the input of baseband signal processing block 104 can be expressed as

$$\begin{matrix}y ( n ) = {\sum }_{l = 0}^{⌈ \frac{L}{P} ⌉} [ {H}_{l} \cdot u ( n - l ) + w ( n ) \\ = {\sum }_{l = 0}^{⌈ \frac{L}{P} ⌉} [ {H}_{l} \cdot S ( n - l ) \cdot A \cdot b ( n - l ) ] + w ( n ) \\ = {H}_{0} \cdot S ( n ) \cdot A \cdot b ( n ) + {\sum }_{l = 1}^{⌈ \frac{L}{P} ⌉} [ {H}_{l} \cdot S ( n - l ) \cdot A \cdot b ( n - l ) ] + w ( n )\end{matrix} \qquad ( 2 )$$

where H₀·S(n) causes the inter-code interference,

$${\sum }_{l = 1}^{⌈ \frac{L}{P} ⌉} {H}_{l} \cdot S ( n - l ) \cdot A \cdot b ( n - l )$$

constitutes the inter-symbol interference caused by previous symbols and w(n) denotes the additive white Gaussian noise (AWGN). The AWGN is represented with covariance matrix σ²I_{K×K} (where I_{K×K} is a K×K identity matrix).

The inter-symbol interference caused by previous symbols,

$${\sum }_{l = 1}^{⌈ \frac{L}{P} ⌉} {H}_{l} \cdot S ( n - l ) \cdot A \cdot b ( n - l ) ,$$

can be replicated by storing previous recovered symbols and multiplying them with corresponding code and channel matrices. The inter-symbol interference can be removed from the received baseband signal using a feedback loop as shown in FIG. 2. Let \overline{b}(n)_{K×1}=[\overline{b}₁(n) \overline{b}₂(n) . . . \overline{b}_{K}(n)]^{T} represent the received symbols at time n. The modified received baseband signal 202, after feedback loop subtraction, is thus

$$y ( n ) - {\sum }_{l = 1}^{⌈ \frac{L}{P} ⌉} {H}_{l} \cdot S ( n - l ) \cdot A \cdot \overline{b} ( n - l ) .$$

If previous symbols are received correctly,

$$y ( n ) - {\sum }_{l = 1}^{⌈ \frac{L}{P} ⌉} {H}_{l} \cdot S ( n - l ) \cdot A \cdot \overline{b} ( n - l ) = {H}_{0} \cdot S ( n ) \cdot A \cdot b ( n ) + w ( n ) .$$

As shown in FIG. 2, a block filter G(n)={[H₀·S(n)]^{H}·H₀·S(n)}⁻¹·[H₀·S(n)]^{H} is applied to the modified received baseband signal 202 to decorrelate the signals so that the inter-code interference is canceled. The final recovered signals are represented by:

$$\begin{matrix}A \cdot \overline{b} ( n ) = G ( n ) \cdot [ y ( n ) - {\sum }_{l = 1}^{⌈ \frac{L}{P} ⌉} {H}_{l} \cdot S ( n - l ) \cdot A \cdot \overline{b} ( n - l ) ] \\ = {\{ {[ {H}_{0} \cdot S ( n ) ]}^{H} \cdot {H}_{0} \cdot S ( n ) \}}^{- 1} \cdot {[ {H}_{0} \cdot S ( n ) ]}^{H} [ {H}_{0} \cdot S ( n ) \cdot A \cdot b ( n ) + w ( n ) ] \\ = A \cdot b ( n ) + {\{ {[ {H}_{0} \cdot S ( n ) ]}^{H} \cdot {H}_{0} \cdot S ( n ) \}}^{- 1} \cdot {[ {H}_{0} \cdot S ( n ) ]}^{H} \cdot w ( n )\end{matrix} \qquad ( 3 )$$

where

A·b(n) are the original signals and

{[H₀·S(n)]^{H}·H₀·S(n)}⁻¹·[H₀·S(n)]^{H}·w(n) represent the noise in the recovered signals.

From the above, it is shown that the receiver and method of the present invention can retrieve information for symbol bₖ(n), 1≦k≦K, without inter-code and inter-symbol interference.

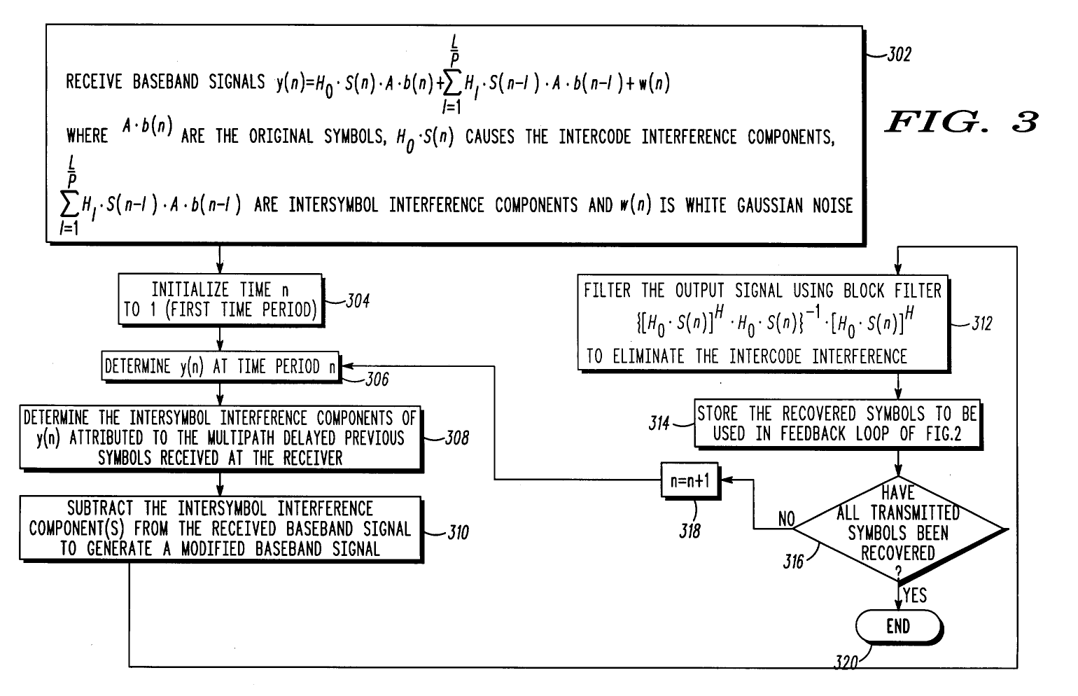

FIG. 3 is a flow diagram of the preferred embodiment of the method of mitigating inter-code and inter-symbol interferences in a communication signal. The method may be implemented in software on any microprocessor or computer commonly known in the art. The invention may also be implemented in hardware using discrete circuits, field programmable gate array (FPGA), or an application-specific integrated circuit (ASIC) designed to perform the functions shown in FIG. 2.

At step 302, the baseband signal processing block 104 receives baseband signals

$$y ( n ) = {H}_{0} \cdot S ( n ) \cdot A \cdot b ( n ) + {\sum }_{l = 1}^{⌈ \frac{L}{P} ⌉} {H}_{l} \cdot S ( n - l ) \cdot A \cdot b ( n - l ) + w ( n ) .$$

At step 304, the method initializes time period n to 1. At step 306, the method determines

$$y ( 1 ) = {H}_{0} \cdot S ( 1 ) \cdot A \cdot b ( 1 ) + {\sum }_{l = 1}^{⌈ \frac{L}{P} ⌉} {H}_{l} \cdot S ( 1 - l ) \cdot A \cdot b ( 1 - l ) + w ( 1 ) .$$

In the current example, it is assumed that

$$⌈ \frac{L}{P} ⌉ = 4 ,$$

i.e., 4 previous symbols have contributions to the inter-symbol interferences of the current symbol experiences. Thus, for l=1 to 4,

y(1)=H₀·S(1)·A·b(1)+H₁·S(0)·A·b(0)+H₂·S(−1)·A·b(−1)+H₃·S(−2)·A·b(−2)+H₄·S(−3)·A·b(−3)+w(1).

At the first time period, there are no delayed signals and b(0), b(−1), b(−2) and b(−3) are equal to zero. Thus, y(1)=H₀·S(1)·A·b(1)+w(1). At step 308, the method determines the inter-symbol interference components of y(1) caused by multipath delays and attributed to the previous symbols. Because n=1 in the present example, the method determines that there are no previous symbols contributing to inter-symbol interference components. Thus, at step 310, there are no previous inter-symbol interference components to subtract from y(1). Thus, the value of the feedback loop shown in FIG. 2 is zero. At step 312, the method filters y(1) using block filter {[H₀·S(1)]^{H}·H₀·S(1)}⁻¹·[H₀·S(1)]^{H} to eliminate the inter-code interference. In particular, the method multiplies H₀·S(1)·A·b(1)+w(1) by {[H₀·S(1)]^{H}·H₀·S(1)}⁻¹·[H₀·S(1)]^{H} to obtain y(1)=A·b(1)+{[H₀·S(1)]^{H}·H₀·S(1)}⁻¹·[H₀·S(1)]^{H}·w(n). The filter component cancels the inter-code interference caused by H₀·S(1), obtaining the recovered symbols of A·b(1). At step 314, the method stores the recovered symbols of A·b(1) so that they can be used in the feedback loop of FIG. 2 to replicate the inter-symbol interference in future time periods.

At step 316, the method determines whether all transmitted symbols have been recovered. If the answer is yes, the method ends at step 320. If the answer is no, the method increments n to 2 at step 318 and returns to step 306 to continue processing. At step 306, the method determines

y(2)=H₀·S(2)·A·b(2)+H₁·S(1)·A·b(1)+H₂·S(0)·A·b(0)+H₃·S(−1)·A·b(−1)+H₄S(−2)·A·b(−2)+w(2).

At the second time period, b(2) and b(1) are non zero values ((b(1) is attributable to the symbols previously recovered at time period n=1) and b(0), b(−1) and b(−2) are equal to zero. Thus, y(2)=H₀·S(2)·A·b(2)+H₁·S(1)·A·b(1)+w(2). At step 308, the method determines the inter-symbol interference components of y(2) caused by multipath delays and attributed to the previous symbols. With n=2 in the present example, the method determines that there is one previous symbol contributing to inter-symbol interference components. Thus, at step 310, the method utilizes the feedback loop of FIG. 2 and subtracts the previous inter-symbol interference component from y(2) to obtain the modified received baseband signal 202. In particular, the method retrieves the stored recovered symbols of A·b(1), multiplies it by S(1) and H₁ and subtracts the product from y(2) to yield:

y(2)=H₀·S(2)·A·b(2)+H₁·S(1)·A·b(1)+w(2)−H₁·S(1)·A·b(1)=H₀·S(2)·A·b(2)+w(2)

At step 312, the method filters y(2) using block filter {[H₀·S(2)]^{H}·H₀·S(2)}⁻¹·[H₀·S(2)]^{H} to eliminate the inter-code interference caused by H₀·S(2). The method multiplies H₀·S(2)·A·b(2)+w(2) by {[H₀·S(2)]^{H}·H₀·S(2)}⁻¹·[H₀·S(2)]^{H} to obtain y(2)=A·b(2)+{[H₀·S(2)]^{H}·H₀·S(2)}⁻¹·[H₀·S(2)]^{H}·w(2). The filter component cancels the inter-code interference caused by H₀·S(2), obtaining the recovered symbols of A·b(2). At step 314, the method stores the recovered symbols of A·b(2) so that they can be used in the feedback loop of FIG. 2 to replicate the inter-symbol interference in future time periods.

At step 316, the method determines whether all transmitted symbols have been recovered. If the answer is yes, the method ends at step 320. If the answer is no, the method increments n to 3 at step 318 and returns to step 306 to continue processing. At step 306, the method determines

y(3)=H₀·S(3)·A·b(3)+H₁·S(2)·A·b(2)+H₂·S(1)·A·b(1)+H₃·S(0)·A·b(0)+H₄·S(−1)·A·b(−1)+w(3).

At the third time period, b(3), b(2) and b(1) are non zero values ((b(1)and b(2) are attributable to the symbols previously recovered at time periods n=1 and 2, respectively) and b(0), and b(−1) are equal to zero. Thus, y(3)=H₀·S(3)·A·b(3)+H₁·S(2)·A·b(2)+H₂·S(1)·A·b(1)+w(3). At step 308, the method determines the inter-symbol interference components of y(3) caused by multipath delays and attributed to the previous symbols. With n=3 in the present example, the method determines that there are two previous symbols contributing to inter-symbol interference components. Thus, at step 310, the method utilizes the feedback loop of FIG. 2 and subtracts the inter-symbol interference components from y(3) to obtain the modified received baseband signal 202. In particular, the method retrieves the stored recovered symbols of A·b(1), multiplies it by S(1)and H₂, retrieves the stored recovered symbols of A·b(2), multiplies it by S(2) and H₁, and subtracts the products from y(3) to yield:

y(3)=H₀·S(3)·A·b(3)+H₁·S(2)·A·b(2)+H₂·S(1)·A·b(1)+w(3)−H₁·S(2)·A·b(2)−H₂·S(1)·A·b(1)=H₀·S(3)·A·b(3)+w(3).

At step 312, the method filters y(3) using block filter {[H₀·S(3)]^{H}·H₀·S(3)}⁻¹·[H₀·S(3)]^{H} to eliminate the inter-code interference caused by H₀·S(3). The method multiplies H₀·S(3)·A·b(3)+w(3) by {[H₀·S(3)]^{H}·H₀·S(3)}⁻¹·[H₀·S(3)]^{H} to obtain y(3)=A·b(3)+{[H₀·S(3)]^{H}·H₀·S(3)}⁻¹·[H₀·S(3)]^{H}·w(3). The filter component cancels the inter-code interference caused by H₀·S(3), obtaining the recovered symbols of A·b(3). At step 314, the method stores the recovered symbols of A·b(3) so that they can be used in the feedback loop of FIG. 2 to replicate the inter-symbol interference in future time periods.

At step 316, the method determines whether all transmitted symbols have been recovered. If the answer is no, n is incremented and the method continues processing at step 306 as previously described. If the answer is yes, the method ends at step 320.

While the invention may be susceptible to various modifications and alternative forms, a specific embodiment has been shown by way of example in the drawings and has been described in detail herein. However, it should be understood that the invention is not intended to be limited to the particular forms disclosed. Rather, the invention is to cover all modifications, equivalents and alternatives falling within the spirit and scope of the invention as defined by the following appended claims.

What is claimed is:

1. A method of mitigating inter-code and inter-symbol interferences in a received signal comprising the steps of:
a) receiving the signal in a time period, n;
b) determining inter-symbol interference components of the signal caused by multipath delays and attributed to previously transmitted symbols;
c) removing each of the inter-symbol interference components using a feedback loop, thereby generating a modified received signal; and
d) filtering the modified received signal to eliminate the inter-code interference.

2. The method of claim 1 wherein the step of removing each of the inter-symbol interference components comprises subtracting each of the inter-symbol interference components attributed to the previously transmitted symbols from the received signal to produce recovered symbols.

3. The method of claim 2 further comprising the step of storing the recovered symbols.

4. The method of claim 2 wherein the step of determining inter-symbol interference components comprises replicating the inter-symbol interference components due to multipath delays:
$${\sum }_{l = 1}^{⌈ \frac{L}{P} ⌉} {H}_{l} \cdot S ( n - l ) \cdot A \cdot b ( n - l ) .$$

5. The method of claim 1 wherein the step of filtering the modified received signal to eliminate the inter-code interference comprises multiplying the modified received signal by a block filter {[H₀·S(n)]^{H}·H₀·S(n)}⁻¹·[H₀·S(n)]^{H}.

6. A method of mitigating inter-code and inter-symbol interferences in a signal comprising the steps of:
for a time period n,
receiving the signal
$$y ( n ) = {H}_{0} \cdot S ( n ) \cdot A \cdot b ( n ) + {\sum }_{l = 1}^{⌈ \frac{L}{P} ⌉} {H}_{l} \cdot S ( n - l ) \cdot A \cdot b ( n - l ) + w ( n ) ;$$
determining inter-symbol interference components of the signal attributed to previously transmitted symbols;
subtracting the inter-symbol interference components from the signal to produce a modified signal; and
filtering the modified signal to remove inter-code interference components and produce recovered symbols.

7. A receiver for mitigating inter-code and inter-symbol interferences in a received signal comprising:
a receiver front end for receiving a transmitted signal and converting the received signal into a baseband signal;
a baseband signal processing block operatively coupled to the receiver front end for mitigating inter-code and inter-symbol interferences in the baseband signal by receiving the baseband signal in a time period, n, determining inter-symbol interference components of the baseband signal caused by multipath delays and attributed to previously transmitted signals, removing each of the inter-symbol interference components attributed to the previously transmitted symbols thereby generating a modified baseband signal, and filtering the modified baseband signal to eliminate the inter-code interference and produce recovered symbols; and
a back end operatively coupled to the baseband signal processing block for receiving the recovered symbols and routing the symbols to an intended application.
